(19) United States
(12) Patent Application Publication
(10) Pub. No.: US 2010/0313935 A1
(43) Pub. Date: Dec. 16, 2010

(54) PHOTOVOLTAIC MODULES AND METHODS FOR MANUFACTURING PHOTOVOLTAIC MODULES HAVING TANDEM SEMICONDUCTOR LAYER STACKS

(75) Inventors: Kevin Michael Coakley, Palo Alto, CA (US); Guleid Hussen, Mountain View, CA (US); Jason Stephens, Mountain View, CA (US); Kunal Girotra, Mountain View, CA (US); Samuel Rosenthal, San Francisco, CA (US)

Correspondence Address: THE SMALL PATENT LAW GROUP LLP, 225 S. MERAMEC, STE. 725T, ST. LOUIS, MO, 63105, US

(73) Assignee: THINSILICION CORPORATION, Mountain View, CA (US)

(21) Appl. No.: 12/796,378

(22) Filed: Jun. 8, 2010

Related U.S. Application Data
(60) Provisional application No. 61/185,770, filed on Jun. 10, 2009.
(60) Provisional application No. 61/221,816, filed on Jun. 30, 2009.
(60) Provisional application No. 61/230,790, filed on Aug. 3, 2009.

(51) Int. Cl. H01L 31/06; H01L 31/18

(52) U.S. Cl. 136/249; 438/59; 257/E31.043; 257/E31.047

(57) ABSTRACT

A monolithically-integrated photovoltaic module is provided. The module includes an insulating substrate and a lower electrode above the substrate. The method also includes a lower stack of microcrystalline silicon layers above the lower electrode, an upper stack of amorphous silicon layers above the lower stack, and an upper electrode above the upper stack. The upper and lower stacks of silicon layers have different energy band gaps. The module also includes a built-in bypass diode vertically extending in the upper and lower stacks of silicon layers from the lower electrode to the upper electrode. The built-in bypass diode includes portions of the lower and upper stacks that have a greater crystalline portion than a remainder of the lower and upper stacks.

### CROSS-REFERENCE TO RELATED APPLICATIONS

This application is a nonprovisional patent application of, and claims priority benefit from, co-pending U.S. Provisional Patent Application Ser. No. 61/185,770, entitled “Photovoltaic Devices Having Tandem Semiconductor Layer Stacks” (the “'770 Application”), and filed on Jun. 10, 2009; co-pending U.S. Provisional Patent Application Ser. No. 61/221,816, entitled “Photovoltaic Devices Having Multiple Semiconductor Layer Stacks” (the “'816 Application”), and filed on Jun. 30, 2009; and co-pending U.S. Provisional Patent Application Ser. No. 61/230,790, entitled “Photovoltaic Devices Having Multiple Semiconductor Layer Stacks” (the “'790 Application”), and filed on Aug. 3, 2009. The entire disclosure of the '770, '816, and '790 Applications are incorporated by reference herein in their entirety.

### BACKGROUND OF THE INVENTION

The subject matter described herein relates to photovoltaic devices. Some known photovoltaic devices include thin film solar modules having active portions of thin films of silicon. Light that is incident onto the modules passes into the active silicon films. If the light is absorbed by the silicon films, the light may generate electrons and holes in the silicon. The electrons and holes are used to create an electric potential and/or an electric current that may be drawn from the modules and applied to an external electric load.

Photons in the light excite electrons in the silicon films and cause the electrons to separate from atoms in the silicon films. In order for the photons to excite the electrons and cause the electrons to separate from the atoms in the films, the photons must have an energy that exceeds the energy band gap in the silicon films. The energy of the photons is related to the wavelengths of light that is incident on the films. Therefore, light is absorbed by the silicon films based on the energy band gap of the films and the wavelengths of the light.

Some known photovoltaic devices include tandem layer stacks that include two or more sets of silicon films deposited on top of one another and between a lower electrode and an upper electrode. The different sets of films may have different energy band gaps. Providing different sets of films with different band gaps may increase the efficiency of the devices as more wavelengths of incident light can be absorbed by the devices. For example, a first set of films may have a greater energy band gap than a second set of films. Some of the light having wavelengths associated with an energy that exceeds the energy band gap of the first set of films is absorbed by the first set of films to create electron-hole pairs. Some of the light having wavelengths associated with energy that does not exceed the energy band gap of the first set of films passes through the first set of films without creating electron-hole pairs. At least a portion of this light that passes through the first set of films may be absorbed by the second set of films if the second set of films has a lower energy band gap.

In order to provide different sets of films with different energy band gaps, the silicon films may be alloyed with germanium to change the band gap of the films. But, alloying the films with germanium tends to reduce the deposition rate that can be used in manufacturing. Furthermore, silicon films alloyed with germanium tend to be more prone to light-induced degradation than those with no germanium. Additionally, germane, the source gas used to deposit silicon-germanium alloy, is costly and hazardous.

As an alternative to alloying silicon films with germanium, the energy band gap of silicon films in a photovoltaic device may be reduced by depositing the silicon films as microcrystalline silicon films instead of amorphous silicon films. Amorphous silicon films typically have larger energy band gaps than silicon films that are deposited in a microcrystalline state. Some known photovoltaic devices include semiconductor layer stacks having amorphous silicon films stacked in series with a microcrystalline silicon films. In such devices, the amorphous silicon films are deposited in a relatively small thickness to reduce carrier transport-related losses in the junction. For example, the amorphous silicon films may be deposited with a small thickness to reduce the amount of electrons and holes that are excited from silicon atoms by incident light and recombine with other silicon atoms or other electrons and holes before reaching the top or bottom electrodes. The electrons and holes that do not reach the electrodes do not contribute to the voltage or current created by the photovoltaic device. But, as the thickness of the amorphous silicon junction is reduced, less light is absorbed by the amorphous silicon junction and the flow of photocurrent in the silicon films is reduced. As a result, the efficiency of the photovoltaic device in converting incident light into electric current can be limited by the amorphous silicon junction in the device stack.

In some photovoltaic devices having relatively thin amorphous silicon films, the surface area of photovoltaic cells in the device that have the active amorphous silicon films may be increased relative to inactive areas of the cells. The active areas include the silicon films that convert incident light into electricity while non-active or inactive areas include portions of the cells where the silicon film is not present or that do not convert incident light into electricity. The electrical power generated by photovoltaic devices may be increased by increasing the active areas of the photovoltaic cells in the device relative to the inactive areas in the device. For example, increasing the width of the cells in a monolithically-integrated thin film photovoltaic module having active amorphous silicon films increases the fraction or percentage of active photovoltaic material in the module that is exposed to sunlight. As the fraction of active photovoltaic material increases, the total photocurrent generated by the device may increase.

Increasing the width of the cells also increases the size or area of light-transmissive electrodes of the device. The light-transmissive electrodes are the electrodes that conduct electrons or holes created in the cells to create the voltage or current of the device. As the size or area of the light-transmissive electrodes increases, the electrical resistance (R) of the light-transmissive electrodes also increases. The electric current (I) that passes through the light-transmissive electrodes also may increase. As the current passing through the light-transmissive electrodes and the resistance of the light-transmissive electrodes increase, energy losses, such as I²R losses, in the photovoltaic device increase. As the energy losses increase, the photovoltaic device becomes less efficient and less power is generated by the device. Therefore, in monolithically-integrated thin film photovoltaic devices, there exists a trade-off between the fraction of active photovoltaic material in the devices and the energy losses incurred in the transparent conducting electrodes of the devices.

A need exists for photovoltaic devices having increased efficiency in converting incident light into electric current and/or with decreased energy losses.

### BRIEF DESCRIPTION OF THE INVENTION

In one embodiment, a monolithically-integrated photovoltaic module is provided. The module includes an insulating substrate and a lower electrode above the substrate. The method also includes a lower stack of microcrystalline silicon layers above the lower electrode, an upper stack of amorphous silicon layers above the lower stack, and an upper electrode above the upper stack. The upper and lower stacks of silicon layers have different energy band gaps. The module also includes a built-in bypass diode vertically extending in the upper and lower stacks of silicon layers from the lower electrode to the upper electrode. The built-in bypass diode includes portions of the lower and upper stacks that have a greater crystalline portion than a remainder of the lower and upper stacks.

In another embodiment, a method of manufacturing a photovoltaic module is provided. The method includes providing a substrate and depositing a lower electrode above the substrate. The method also includes depositing a lower stack of microcrystalline silicon layers above the lower electrode, depositing an upper stack of amorphous silicon layers above the lower stack of microcrystalline silicon layers, and depositing an upper electrode above the upper stack of amorphous silicon layers. At least one of the lower stack and the upper stack includes an N-I-P stack of silicon layers having an n-doped silicon layer, an intrinsic silicon layer, and a p-doped silicon layer. The intrinsic silicon layer has an energy band gap that is reduced by depositing the intrinsic silicon layer at a temperature of at least 250 degrees Celsius.

In another embodiment, another method of manufacturing a photovoltaic module is provided. The method includes providing a substrate and a lower electrode and depositing a lower stack of microcrystalline silicon layers above the lower electrode. The method also includes depositing an upper stack of amorphous silicon layers above the lower stack and providing an upper electrode above the upper stack of amorphous silicon. The method further includes increasing a crystallinity of the lower stack and of the upper stack by removing a portion of the upper electrode. The crystallinity of the lower and upper stacks is increased to form a built-in bypass diode that extends from the lower electrode to the upper electrode and through the lower stack and the upper stack.

### BRIEF DESCRIPTION OF THE DRAWINGS

FIG. 1 is a schematic view of a photovoltaic cell in accordance with one embodiment.

FIG. 2 schematically illustrates structures in a template layer shown in FIG. 1 in accordance with one embodiment.

FIG. 3 schematically illustrates structures in the template layer shown in FIG. 1 in accordance with another embodiment.

FIG. 4 schematically illustrates structures in the template layer shown in FIG. 1 in accordance with another embodiment.

FIG. 5 is a schematic diagram of a photovoltaic device and a magnified view of the device according to one embodiment.

FIG. 6 is a flowchart of a process for manufacturing a photovoltaic device in accordance with one embodiment.

The foregoing summary, as well as the following detailed description of certain embodiments of the presently described technology, will be better understood when read in conjunction with the appended drawings. For the purpose of illustrating the presently described technology, certain embodiments are shown in the drawings. It should be understood, however, that the presently described technology is not limited to the arrangements and instrumentality shown in the attached drawings. Moreover, it should be understood that the components in the drawings are not to scale and the relative sizes of one component to another should not be construed or interpreted to require such relative sizes.

### DETAILED DESCRIPTION OF THE INVENTION

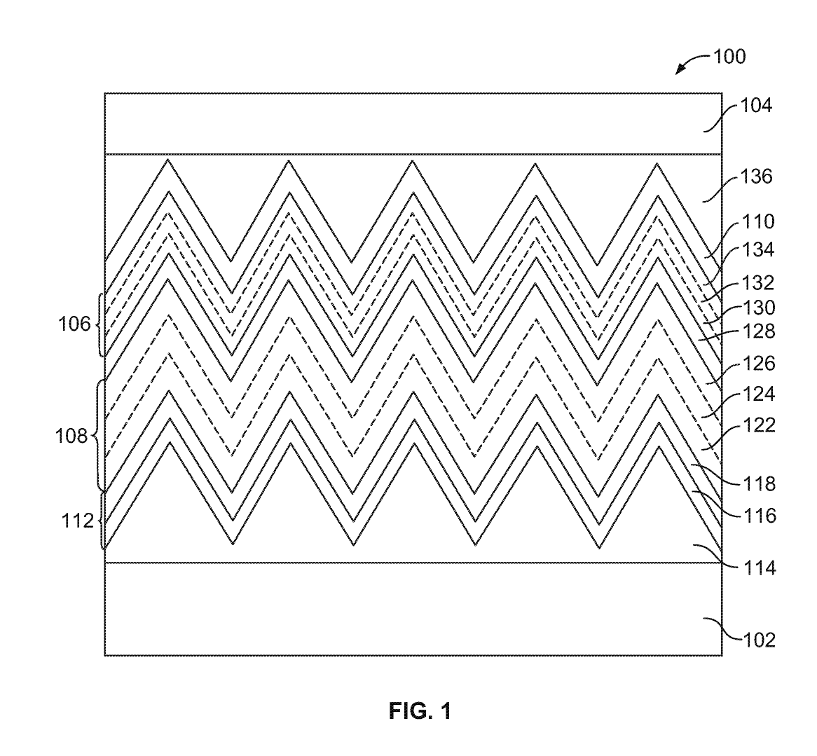

FIG. 1 is a schematic view of a photovoltaic cell 100 in accordance with one embodiment. The cell 100 includes a substrate 102 and a light transmissive cover layer 104 with upper and lower active silicon layer stacks 106, 108 disposed between upper and lower electrode layers 110, 112, or electrodes 110, 112. The upper and lower electrode layers 110, 112 and the upper and lower layer stacks 106, 108 are located between the substrate 102 and cover layer 104. The cell 100 is a substrate-configuration photovoltaic cell. For example, light that is incident on the cell 100 on the cover layer 104 opposite the substrate 102 passes into and is converted into an electric potential by active silicon layer stacks 106, 108 of the cell 100. The light passes through the cover layer 104 and additional layers and components of the cell 100 to the upper and lower layer stacks 106, 108. The light is absorbed by the upper and lower layer stacks 106, 108.

Photons in the incident light that is absorbed by the upper and lower layer stacks 106, 108 excite electrons in the upper and lower layer stacks 106, 108 and cause the electrons to separate from atoms in the upper and lower layer stacks 106, 108. Complementary positive charges, or holes, are created when the electrons separate from the atoms. The upper and lower layer stacks 106, 108 have different energy band gaps that absorb different portions of the spectrum of wavelengths in the incident light. The electrons drift or diffuse through the upper and lower layer stacks 106, 108 and are collected at one of the upper and lower electrode layers 110, 112. The holes drift or diffuse through the upper and lower layer stacks 106, 108 and are collected at the other of the upper and lower electrode layers 110, 112. The collection of the electrons and holes at the upper and lower electrode layers 110, 112 generates an electric potential difference in the cell 100. The voltage difference in the cell 100 may be added to the potential difference that is generated in additional cells (not shown). The potential difference generated in a plurality of cells 100 serially coupled with one another may be added together to increase the total potential difference generated by the cells 100. Electric current is generated by the flow of electrons and holes between neighboring cells 100. The current may be drawn from the cells 100 and applied to an external electric load.

The components and layers of the cell 100 are schematically illustrated in FIG. 1, and the shape, orientation and relative sizes of the components and layers are not intended to be limiting. The substrate 102 is located at the bottom of the cell 100. The substrate 102 provides mechanical support to the other layers and components of the cell 100. The substrate 102 includes, or is formed from, a dielectric material, such as a non-conductive material. The substrate 102 may be formed from a dielectric having a relatively low softening point, such as one or more dielectric materials having a softening point below about 750 degrees Celsius. By way of example only, the substrate 102 may be formed from soda-lime float glass, low iron float glass or a glass that includes at least 10 percent by weight of sodium oxide (Na₂O). In another example, the substrate may be formed from another type of glass, such as float glass or borosilicate glass. Alternatively, the substrate 102 is formed from a ceramic, such as silicon nitride (Si₃N₄) or aluminum oxide (alumina, or Al₂O₃). In another embodiment, the substrate 102 is formed from a conductive material, such as a metal. By way of example only, the substrate 102 may be formed from stainless steel, aluminum, or titanium.

The substrate 102 has a thickness that is sufficient to mechanically support the remaining layers of the cell 100 while providing mechanical and thermal stability to the cell 100 during manufacturing and handling of the cell 100. The substrate 102 is at least approximately 0.7 to 5.0 millimeters thick in one embodiment. By way of example only, the substrate 102 may be an approximately 2 millimeter thick layer of float glass. Alternatively, the substrate 102 may be an approximately 1.1 millimeter thick layer of borosilicate glass. In another embodiment, the substrate 102 may be an approximately 3.3 millimeter thick layer of low iron or standard float glass.

A textured template layer 114 may be deposited above the substrate 102. Alternatively, the template layer 114 is not included in the cell 100. The template layer 114 is a layer having a controlled and predetermined three dimensional texture that imparts the texture onto one or more of the layers and components in the cell 100 that are deposited onto or above the template layer 114. In one embodiment, the texture template layer 114 may be deposited and formed in accordance with one of the embodiments described in co-pending U.S. Nonprovisional patent application Ser. No. 12/762,880, entitled “Photovoltaic Cells And Methods To Enhance Light Trapping In Thin Film Silicon,” and filed Apr. 19, 2010 (“'880 Application”). The entire disclosure of the '880 Application is incorporated by reference herein in its entirety. With respect to the '880 Application, the template layer 114 described herein may be similar to the template layer 136 described in the '880 Application and include an array of one or more of the structures 300, 400, 500 described and illustrated in the '880 Application.

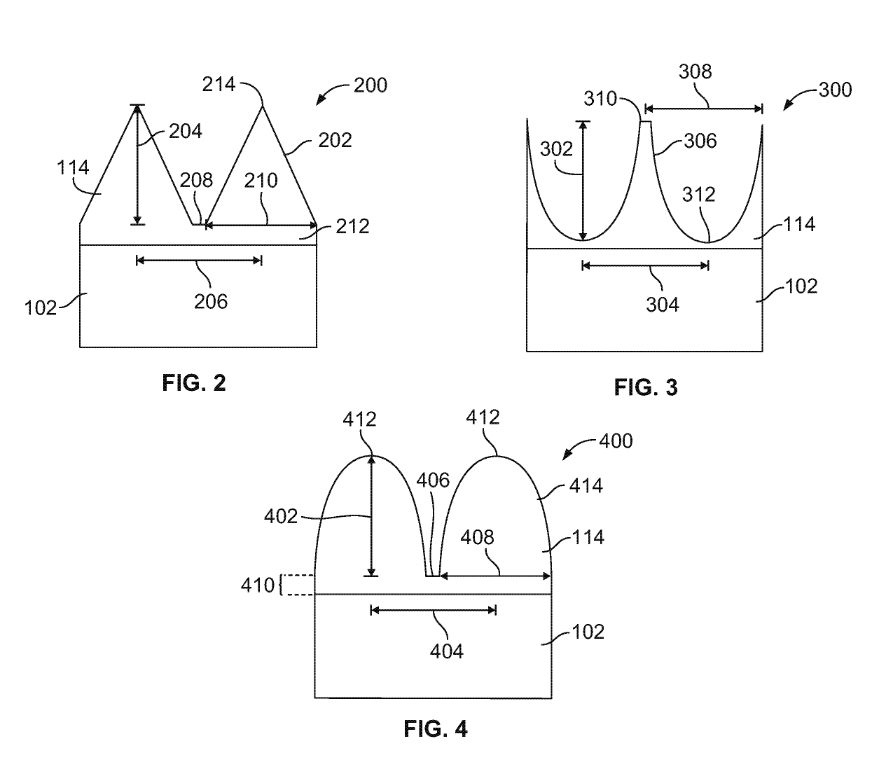

The texture of the template layer 114 in the illustrated embodiment may be determined by the shape and dimensions of one or more structures 200, 300, 400 (shown in FIGS. 2 through 4) of the template layer 114. The template layer 114 is deposited above the substrate 102. For example, the template layer 114 may directly deposited onto the substrate 102.

FIG. 2 schematically illustrates peak structures 200 in the template layer 114 in accordance with one embodiment. The peak structures 200 are created in the template layer 114 to impart a predetermined texture in layers above the template layer 114. The structures 200 are referred to as peak structures 200 as the structures 200 appear as sharp peaks along an upper surface 202 of the template layer 114. The peak structures 200 are defined by one or more parameters, including a peak height (Hpk) 204, a pitch 206, a transitional shape 208, and a base width (Wb) 210. As shown in FIG. 2, the peak structures 200 are formed as shapes that decrease in width as the distance from the substrate 102 increases. For example, the peak structures 200 decrease in size from bases 212 located at or near the substrate 102 to several peaks 214. The peak structures 200 are represented as triangles in the two dimensional view of FIG. 2, but alternatively may have a pyramidal or conical shape in three dimensions.

The peak height (Hpk) 204 represents the average or median distance of the peaks 214 from the transitional shapes 208 between the peak structures 200. For example, the template layer 114 may be deposited as an approximately flat layer up to the bases 212 of the peaks 214, or to the area of the transitional shape 208. The template layer 114 may continue to be deposited in order to form the peaks 214. The distance between the bases 212 or transitional shape 208 to the peaks 214 may be the peak height (Hpk) 204.

The pitch 206 represents the average or median distance between the peaks 214 of the peak structures 200. The pitch 206 may be approximately the same in two or more directions. For example, the pitch 206 may be the same in two perpendicular directions that extend parallel to the substrate 102. In another embodiment, the pitch 206 may differ along different directions. Alternatively, the pitch 206 may represent the average or median distance between other similar points on adjacent peak structures 200. The transitional shape 208 is the general shape of the upper surface 202 of the template layer 114 between the peak structures 200. As shown in the illustrated embodiment, the transitional shape 208 can take the form of a flat “facet.” Alternatively, the flat facet shape may be a cone or pyramid when viewed in three dimensions. The base width (Wb) 210 is the average or median distance across the peak structures 200 at an interface between the peak structures 200 and the base 212 of the template layer 114. The base width (Wb) 210 may be approximately the same in two or more directions. For example, the base width (Wb) 210 may be the same in two perpendicular directions that extend parallel to the substrate 102. Alternatively, the base width (Wb) 210 may differ along different directions.

FIG. 3 illustrates valley structures 300 of the template layer 114 in accordance with one embodiment. The shapes of the valley structures 300 differ from the shapes of the peak structures 200 shown in FIG. 2 but may be defined by the one or more of the parameters described above in connection with FIG. 2. For example, the valley structures 300 may be defined by a peak height (Hpk) 302, a pitch 304, a transitional shape 306, and a base width (Wb) 308. The valley structures 300 are formed as recesses or cavities that extend into the template layer 114 from an upper surface 310 of the valley structures 300. The valley structures 300 are shown as having a parabolic shape in the two dimensional view of FIG. 3, but may have conical, pyramidal, or paraboloid shapes in three dimensions. In operation, the valley structures 300 may vary slightly from the shape of an ideal parabola.

In general, the valley structures 300 include cavities that extend down into the template layer 114 from the upper surface 310 and toward the substrate 102. The valley structures 300 extend down to low points 312, or nadirs, of the template layer 114 that are located between the transition shapes 306. The peak height (Hpk) 302 represents the average or median distance between the upper surface 310 and the low points 312. The pitch 304 represents the average or median distance between the same or common points of the valley structures 300. For example, the pitch 304 may be the distance between the midpoints of the transition shapes 306 that extend between the valley structures 300. The pitch 304 may be approximately the same in two or more directions. For example, the pitch 304 may be the same in two perpendicular directions that extend parallel to the substrate 102. In another embodiment, the pitch 304 may differ along different directions. Alternatively, the pitch 304 may represent the distance between the low points 312 of the valley structures 300. Alternatively, the pitch 304 may represent the average or median distance between other similar points on adjacent valley structures 300.

The transitional shape 306 is the general shape of the upper surface 310 between the valley structures 300. As shown in the illustrated embodiment, the transitional shape 306 can take the form of a flat “facet.” Alternatively, the flat facet shape may be a cone or pyramid when viewed in three dimensions. The base width (Wb) 308 represents the average or median distance between the low points 312 of adjacent valley structures 300. Alternatively, the base width (Wb) 308 may represent the distance between the midpoints of the transition shapes 306. The base width (Wb) 308 may be approximately the same in two or more directions. For example, the base width (Wb) 308 may be the same in two perpendicular directions that extend parallel to the substrate 102. Alternatively, the base width (Wb) 308 may differ along different directions.

FIG. 4 illustrates rounded structures 400 of the template layer 114 in accordance with one embodiment. The shapes of the rounded structures 400 differ from the shapes of the peak structures 200 shown in FIG. 2 and the valley structures 300 shown in FIG. 3, but may be defined by the one or more of the parameters described above in connection with FIGS. 2 and 3. For example, the rounded structures 400 may be defined by a peak height (Hpk) 402, a pitch 404, a transitional shape 406, and a base width (Wb) 408. The rounded structures 400 are formed as protrusions of an upper surface 414 of the template layer 114 that extend upward from a base film 410 of the template layer 114. The rounded structures 400 may have an approximately parabolic or rounded shape. In operation, the rounded structures 400 may vary slightly from the shape of an ideal parabola. While the rounded structures 400 are represented as parabolas in the two dimensional view of FIG. 4, alternatively the rounded structures 400 may have the shape of a three dimensional paraboloid, pyramid, or cone that extends upward away from the substrate 102.

In general, the rounded structures 400 project upward from the base film 410 and away from the substrate 102 to rounded high points 412, or rounded apexes. The peak height (Hpk) 402 represents the average or median distance between the base film 410 and the high points 412. The pitch 404 represents the average or median distance between the same or common points of the rounded structures 400. For example, the pitch 404 may be the distance between the high points 412. The pitch 404 may be approximately the same in two or more directions. For example, the pitch 404 may be the same in two perpendicular directions that extend parallel to the substrate 102. Alternatively, the pitch 404 may differ along different directions. In another example, the pitch 404 may represent the distance between midpoints of the transition shapes 406 that extend between the rounded structures 400. Alternatively, the pitch 404 may represent the average or median distance between other similar points on adjacent rounded structures 400.

The transitional shape 406 is the general shape of the upper surface 414 between the rounded structures 400. As shown in the illustrated embodiment, the transitional shape 406 can take the form of a flat “facet.” Alternatively, the flat facet shape may be a cone or pyramid when viewed in three dimensions. The base width (Wb) 408 represents the average or median distance between the transition shapes 406 on opposite sides of a rounded structure 400. Alternatively, the base width (Wb) 408 may represent the distance between the midpoints of the transition shapes 406.

In accordance with one embodiment, the pitch 204, 302, 402 and/or base width (Wb) 210, 308, 408 of the structures 200, 300, 400 are approximately 400 nanometers to approximately 1500 nanometers. Alternatively, the pitch 204, 302, 402 of the structures 200, 300, 400 may be smaller than approximately 400 nanometers or larger than approximately 1500 nanometers. The average or median peak height (Hpk) 204, 302, 402 of the structures 200, 300, 400 may be approximately 25 to 80% of the pitch 206, 304, 404 for the corresponding structure 200, 300, 400. Alternatively, the average peak height (Hpk) 204, 302, 402 may be a different fraction of the pitch 206, 304, 404. The base width (Wb) 210, 308, 408 may be approximately the same as the pitch 206, 304, 404. In another embodiment, the base width (Wb) 210, 308, 408 may differ from the pitch 206, 304, 404. The base width (Wb) 210, 308, 408 may be approximately the same in two or more directions. For example, the base width (Wb) 210, 308, 408 may be the same in two perpendicular directions that extend parallel to the substrate 102. Alternatively, the base width (Wb) 210, 308, 408 may differ along different directions.

The parameters of the structures 200, 300, 400 in the template layer 114 may vary based on whether the PV cell 100 (shown in FIG. 1) is a dual- or triple junction cell 100 and/or on which of the semiconductor films or layers in the upper and/or lower layer stacks 106, 108 (shown in FIG. 1) is the current-limiting layer. For example, the upper and lower silicon layer stacks 106, 108 may include two or more stacks of N-I-P and/or P-I-N doped amorphous or doped microcrystalline silicon layers. One or more parameters described above may be based on which of the semiconductor layers in the N-I-P and/or P-I-N stacks is the current-limiting layer. For example, one or more of the layers in the N-I-P and/or P-I-N stacks may limit the amount of current that is generated by the PV cell 100 when light strikes the PV cell 100. One or more of the parameters of the structures 200, 300, 400 may be based on which of these layers is the current-limiting layer.

In one embodiment, if the PV cell 100 (shown in FIG. 1) includes a microcrystalline silicon layer in the upper and/or lower silicon layer stack 106, 108 (shown in FIG. 1) and the microcrystalline silicon layer is the current limiting layer of the upper and lower silicon layer stacks 106, 108, the pitch 206, 304, 404 of the structures 200, 300, 400 in the template layer 114 below the microcrystalline silicon layer may be between approximately 500 and 1500 nanometers. The microcrystalline silicon layer has an energy bandgap that corresponds to infrared light having wavelengths between approximately 500 and 1500 nanometers. For example, the structures 200, 300, 400 may reflect an increased amount of infrared light having wavelengths of between 500 and 1500 nanometers if the pitch 206, 404, 504 is approximately matched to the wavelengths. The transitional shape 208, 306, 406 of the structures 200, 300, 400 may be a flat facet and the base width (Wb) 210, 308, 408 may be 60% to 100% of the pitch 206, 304, 404. The peak height (Hpk) 204, 302, 402 may be between 25% to 75% of the pitch 206, 304, 404. For example, a ratio of the peak height (Hpk) 204, 302, 402 to the pitch 206, 304, 404 may provide scattering angles in the structures 200, 300, 400 that reflect more light back into the upper and/or lower silicon layer stacks 106, 108 relative to other ratios.

In another example, if the PV cell 100 (shown in FIG. 1) includes one layer stack 106 or 108 being amorphous silicon layers and the other layer stack 106 or 108 being microcrystalline semiconductor layers, the range of pitches 206, 304, 404 for the template layer 114 may vary based on which of the upper and lower layer stacks 106, 108 is the current limiting stack. If the upper silicon layer stack 106 includes a microcrystalline N-I-P or P-I-N doped semiconductor layer stack, the lower silicon layer stack 108 includes an amorphous N-I-P or P-I-N doped semiconductor layer stack, and the upper silicon layer stack 106 is the current limiting layer, then the pitch 206, 304, 504 may be between approximately 500 and 1500 nanometers. In contrast, if the lower silicon layer stack 108 is the current limiting layer, then the pitch 206, 304, 404 may be between approximately 350 and 1000 nanometers.

Returning to the discussion of the cell 100 shown in FIG. 1, the template layer 114 may be formed in accordance with one or more of the embodiments described in the '880 Application. For example, the template layer 114 may be formed by depositing an amorphous silicon layer onto the substrate 102 followed by texturing the amorphous silicon using reactive ion etching through silicon dioxide spheres placed on the upper surface of the amorphous silicon. Alternatively, the template layer 114 may be formed by sputtering an aluminum and tantalum bilayer on the substrate 102 and then anodizing the template layer 114. In another embodiment, the template layer may be formed by depositing a film of textured fluorine-doped tin oxide (SnO₂:F) using atmospheric chemical vapor deposition. One or more of these films of the template layer 114 may be obtained from a vendor such as Asahi Glass Company or Pilkington Glass. In an alternative embodiment, the template layer 114 may be formed by applying an electrostatic charge to the substrate 102 and then placing the charged substrate 102 in an environment having oppositely charged particles. Electrostatic forces attract the charged particles to the substrate 102 to form the template layer 114. The particles are subsequently permanently attached to the substrate 102 by depositing an adhesive “glue” layer (not shown) onto the particles in a subsequent deposition step or by annealing the particles and substrate 102. Examples of particle materials include faceted ceramics and diamond like material particles such as silicon carbide, alumina, aluminum nitride, diamond, and CVD diamond.

The lower electrode layer 112 is deposited above the template layer 114. The lower electrode layer 112 is comprised of a conductive reflector layer 116 and a conductive buffer layer 118. The reflector layer 116 is deposited above the template layer 114. For example, the reflector layer 116 may be directly deposited onto the template layer 114. The reflector layer 116 has a textured upper surface 120 that is dictated by the template layer 114. For example, the reflector layer 116 may be deposited onto the template layer 114 such that the reflector layer 116 includes structures (not shown) that are similar in size and/or shape to the structures 200, 300, 400 (shown in FIGS. 2 through 4) of the template layer 114.

The reflector layer 116 may include, or be formed from, a reflective conductive material, such as silver. Alternatively, the reflector layer 116 may include, or be formed from, aluminum or an alloy that includes silver or aluminum. The reflector layer 116 is approximately 100 to 300 nanometers in thickness and may be deposited by sputtering the material(s) of the reflector layer 116 onto the template layer 114.

The reflector layer 116 provides a conductive layer and a reflective surface for reflecting light upward into the upper and lower active silicon layer stacks 106, 108. For example, a portion of the light that is incident on the cover layer 104 and that passes through the upper and lower active silicon layer stacks 106, 108 may not be absorbed by the upper and lower layer stacks 106, 108. This portion of the light may reflect off of the reflector layer 116 back into the upper and lower layer stacks 106, 108 such that the reflected light may be absorbed by the upper and/or lower layer stacks 106, 108. The textured upper surface 120 of the reflector layer 116 increases the amount of light that is absorbed, or “trapped” via partial or full scattering of the light into the upper and lower active silicon layer stacks 106, 108. The peak height (Hpk) 204, 302, 402, pitch 206, 304, 404, transitional shape 208, 306, 406, and/or base width (Wb) 210, 308, 408 (shown in FIGS. 2 through 4)) may be varied to increase the amount of light that is trapped in the upper and lower layer stacks 106, 108 for a desired or predetermined range of wavelengths of incident light.

The buffer layer 118 is deposited above the reflector layer 116 and may be directly deposited onto the reflector layer 116. The buffer layer 118 provides an electric contact to the lower active silicon layer stack 108. For example, the buffer layer 118 may include, or be formed from, a transparent conductive oxide (TCO) material that is electrically coupled with the lower active silicon layer stack 108. In one embodiment, the buffer layer 118 includes aluminum doped zinc oxide, zinc oxide and/or indium tin oxide. The buffer layer 118 may be deposited in a thickness of approximately 50 to 500 nanometers, although a different thickness may be used.

In one embodiment, the buffer layer 118 provides a chemical buffer between the reflector layer 116 and the lower active silicon layer stack 108. For example, the buffer layer 118 may prevent chemical attack on the lower active silicon layer stack 108 by the reflector layer 116 during processing and manufacture of the cell 100. The buffer layer 118 impedes or prevents contamination of the silicon in the lower layer stack 108 and may reduce plasmon absorption losses in the lower layer stack 108.

The buffer layer 118 may provide an optical buffer between the reflector layer 116 and the lower active silicon layer stack 108. For example, the buffer layer 118 may be a light transmissive layer that is deposited in a thickness that is based on a predetermined range of wavelengths that is reflected off of the reflector layer 116. The thickness of the buffer layer 118 may permit certain wavelengths of light to pass through the buffer layer 118, reflect off of the reflector layer 116, pass back through the buffer layer 118 and into the lower layer stack 108. By way of example only, the buffer layer 118 may be deposited at a thickness of approximately 75 to 80 nanometers.

The lower active silicon layer stack 108 is deposited above, or directly onto, the buffer layer 118. In one embodiment, the lower layer stack 108 is deposited at a thickness of approximately 1 to 3 micrometers, although the lower layer stack 108 may be deposited at a different thickness. The lower layer stack 108 includes three sublayers 122, 124, 126 of silicon. In one embodiment, the sublayers 122, 124, 126 are n-doped, intrinsic and p-doped microcrystalline silicon films, respectively, that are deposited using plasma enhanced chemical vapor deposition (PECVD) at relatively low deposition temperatures. For example, the sublayers 122, 124, 126 may be deposited at a temperature in the range of approximately 160 to 250 degrees Celsius. The deposition of the sublayers 122, 124, 126 at relatively lower deposition temperatures may reduce interdiffusion of dopants from one sublayer 122, 124, 126 into another sublayer 122, 124, 126. In addition, use of lower deposition temperatures in a given sublayer 122, 124, 126 may help prevent hydrogen evolution from the underlying sublayers 122, 124, 126 in the upper and lower layer stacks 106, 108, respectively.

Alternatively, the lower layer stack 108 may be deposited at relatively high deposition temperatures. For example, the lower layer stack 108 may be deposited at a temperature in the range of approximately 250 to 350 degrees Celsius. As the deposition temperature increases, the average grain size of crystalline structure in the lower layer stack 108 may increase and may lead to an increase in the absorption of infrared light in the lower layer stack 108. Therefore, the lower layer stack 108 may be deposited at the higher temperatures in order to increase the average grain size of the silicon crystals in the lower layer stack 108. In addition, depositing the lower layer stack 108 at higher temperatures may make the lower layer stack 108 more thermally stable during the subsequent deposition of the upper layer stack 106. As described below, the top sublayer 126 of the lower layer stack 108 may be a p-doped silicon film. In such an embodiment, the bottom and middle sublayers 122, 124 of the lower layer stack 108 may be deposited at the relatively high deposition temperatures within the range of approximately 250 to 350 degrees Celsius while the top sublayer 126 is deposited at a relatively lower temperature within the range of approximately 150 to 250 degrees Celsius. Alternatively, the top sublayer 126 may be deposited at a temperature of at least 160 degrees Celsius. The p-doped sublayer 126 is deposited at the lower temperature to reduce the amount of interdiffusion between the p-doped top sublayer 126 and the intrinsic middle sublayer 124. Alternatively, the p-doped sublayer 126 is deposited at a higher deposition temperature, such as approximately 250 to 350 degrees Celsius, for example.

The sublayers 122, 124, 126 may have an average grain size of at least approximately 10 nanometers. In another embodiment, the average grain size in the sublayers 122, 124, 126 is at least approximately 20 nanometers. Alternatively, the average grain size of the sublayers 122, 124, 126 is at least approximately 50 nanometers. In another embodiment, the average grain size is at least approximately 100 nanometers. Optionally, the average grain size may be at least approximately 1 micrometer. The average grain size in the sublayers 122, 124, 126 may be determined by a variety of methods. For example, the average grain size can be measured using Transmission Electron Microscopy (“TEM”). In such an example, a thin sample of the sublayers 122, 124, 126 is obtained. For example, a sample of one or more of the sublayers 122, 124, 126 having a thickness of approximately 1 micrometer or less is obtained. A beam of electrons is transmitted through the sample. The beam of electrons may be rastered across all or a portion of the sample. As the electrons pass through the sample, the electrons interact with the crystalline structure of the sample. The path of transmission of the electrons may be altered by the sample. The electrons are collected after the electrons pass through the sample and an image is generated based on the collected electrons. The image provides a two-dimensional representation of the sample. The crystalline grains in the sample may appear different from the amorphous portions of the sample. Based on this image, the size of crystalline grains in the sample may be measured. For example, the surface area of several crystalline grains appearing in the image can be measured and averaged. This average is the average crystalline grain size in the sample in the location where the sample was obtained. For example, the average may be the average crystalline grain size in the sublayers 122, 124, 126 from which the sample was obtained.

The bottom sublayer 122 may be a microcrystalline layer of n-doped silicon. In one embodiment, the bottom sublayer 122 is deposited in a PECVD chamber with an operating frequency of approximately 13.56 MHz using a source gas combination of hydrogen (H), silane (SiH₄) and phosphine, or phosphorus trihydride (PH₃) at a vacuum pressure of approximately 2 to 3 ton and at an energy of approximately 500 to 1000 Watts. The ratio of source gases used to deposit the bottom sublayer 122 may be approximately 200 to 300 parts hydrogen gas to approximately 1 part silane to approximately 0.01 part phosphine.

The middle sublayer 124 may be a microcrystalline layer of intrinsic silicon. For example, the middle sublayer 124 may include silicon that is not doped or that has a dopant concentration that less than 10¹⁸/cm³. In one embodiment, the middle sublayer 124 is deposited in a PECVD chamber with an operating frequency of approximately 13.56 MHz using a source gas combination of hydrogen (H) and silane (SiH₄) at a vacuum pressure of approximately 9 to 10 ton and at an energy of approximately 2 to 4 kilowatts. The ratio of source gases used to deposit the middle sublayer 124 may be approximately 50 to 65 parts hydrogen gas to approximately 1 part silane.

The top sublayer 126 may be a microcrystalline layer of p-doped silicon. Alternatively, the top sublayer 126 may be a protocrystalline layer of p-doped silicon. In one embodiment, the top sublayer 126 is deposited in a PECVD chamber with an operating frequency of approximately 13.56 MHz using a source gas combination of hydrogen (H), silane (SiH₄) and trimethyl boron (B(CH₃)₃, or TMB) at a vacuum pressure of approximately 2 to 3 ton and at an energy of approximately 500 to 1000 Watts. The ratio of source gases used to deposit the top sublayer 126 may be approximately 200 to 300 parts hydrogen gas to approximately 1 part silane to approximately 0.01 part phosphine. TMB may be used to dope the silicon in the top sublayer 126 with boron. Using TMB to dope the silicon in the top sublayer 126 may provide better thermal stability than using a different type of dopant, such as boron trifluoride (BF₃) or diborane (B₂H₆). For example, the use of TMB to dope silicon may result in less boron diffusing from the top sublayer 126 into adjacent layers, such as the middle sublayer 124, during the deposition of subsequent layers when compared to using trifluoride or diborane. By way of example only, using TMB to dope the top sublayer 126 may result in less boron diffusing into the middle sublayer 124 than when trifluoride or diborane is used to dope the top sublayer 126 during deposition of the upper layer stack 106.

The three sublayers 122, 124, 126 form an N-I-P junction or N-I-P stack of active silicon layers. As the lower layer stack 108, the three sublayers 122, 124, 126 have an energy band gap of approximately 1.1 eV. Alternatively, the lower layer stack 108 may have a different energy band gap. The lower layer stack 108 has a different energy band gap than the upper layer stack 106, as described below. The different energy band gaps of the upper and lower layer stacks 106, 108 permit the upper and lower layer stacks 106, 108 to absorb different wavelengths of incident light.

In one embodiment, an intermediate reflector layer 128 is deposited between the upper and lower layer stacks 106, 108. For example, the intermediate reflector layer 128 may be deposited directly on the lower layer stack 108. Alternatively, the intermediate reflector layer 128 is not included in the cell 100 and the upper layer stack 106 is deposited onto the lower layer stack 108. The intermediate reflector layer 128 partially reflects light into the upper layer stack 106 and permits some of the light to pass through the intermediate reflector layer 128 and into the lower layer stack 108. For example, the intermediate reflector layer 128 may reflect a subset of the spectrum of wavelengths of light that is incident on the cell 100 back up and into the upper layer stack 106.

The intermediate reflector layer 128 includes, or is formed from, a partially reflective material. For example, the intermediate reflector layer 128 may be formed from titanium dioxide (TiO₂), zinc oxide (ZnO), aluminum doped zinc oxide (AZO), indium tin oxide (ITO), doped silicon oxide or doped silicon nitride. In one embodiment, the intermediate reflector layer 128 is approximately 10 to 200 nanometers in thickness, although a different thickness may be used.

The upper active silicon layer stack 106 is deposited above the lower active silicon layer stack 108. For example, the upper layer stack 106 may be directly deposited onto the intermediate reflector layer 128 or onto the lower layer stack 108. In one embodiment, the upper layer stack 106 is deposited at a thickness of approximately 200 to 400 nanometers, although the upper layer stack 106 may be deposited at a different thickness. The upper layer stack 106 includes three sublayers 130, 132, 134 of silicon.

In one embodiment, the sublayers 130, 132, 134 are n-doped, intrinsic, and p-doped amorphous silicon (a-Si:H) films, respectively, that are deposited using plasma enhanced chemical vapor deposition (PECVD) at relatively low deposition temperatures. For example, the sublayers 130, 132, 134 may be deposited at a temperature of approximately 185 to 250 degrees Celsius. In another example, the sublayers 130, 132, 134 may be deposited at temperatures between 185 and 225 degrees Celsius. Alternatively, the p-doped sublayer 134 is deposited at a temperature that is lower than the temperatures at which the n-doped and intrinsic sublayers 130, 132 are deposited. For example, the p-doped sublayer 134 may be deposited at a temperature of approximately 120 to 200 degrees Celsius while the intrinsic and/or n-doped sublayers 132, 130 are deposited at temperatures of at least 200 degrees Celsius. By way of example only, the intrinsic and/or n-doped sublayers 132, 130 may be deposited at a temperature of approximately 250 to 350 degrees Celsius.

The deposition of one or more of the sublayers 130, 132, 134 at relatively lower deposition temperatures may reduce interdiffusion of dopants between sublayers 122, 124, 126 in the lower layer stack 108 and/or between sublayers 130, 132, 134 in the upper layer stack 106. The diffusion of dopants in and between the sublayers 122, 124, 126 and in and between the sublayers 130, 132, 134 may be based on the temperature at which the sublayers 122, 124, 126 and 130, 132, 134 are heated. For example, the interdiffusion of dopants between the sublayers 122, 124, 126, 130, 132, 134 can increase with exposure to increasing temperatures. Using lower deposition temperatures may reduce the amount of dopant diffusion in the sublayers 122, 124, 126 and/or in the sublayers 130, 132, 134. Use of lower deposition temperatures in a given sublayer 122, 124, 126, 130, 132, 134 may reduce hydrogen evolution from the underlying sublayers 122, 124, 126, 130, 132, 134 in the upper and lower layer stacks 106, 108, respectively.

The deposition of the sublayers 130, 132, 134 at relatively lower deposition temperatures may increase the energy band gap of the upper layer stack 106 relative to amorphous silicon layers that are deposited at higher deposition temperatures. For example, depositing the sublayers 130, 132, 134 as amorphous silicon layers at temperatures between approximately 185 to 250 degrees Celsius may cause the band gap of the upper layer stack 106 to be approximately 1.85 to 1.95 eV. Increasing the band gap of the upper layer stack 106 may cause the sublayers 130, 132, 134 to absorb a smaller subset of the spectrum of wavelengths in the incident light, but may increase the electric potential difference generated in the cell 100.

Alternatively, the upper layer stack 106 may be deposited at relatively high deposition temperatures. For example, the upper layer stack 106 may be deposited at a temperature in the range of approximately 250 to 350 degrees Celsius. As the deposition temperature of amorphous silicon increases, the energy band gap of the silicon decreases. For example, depositing the sublayers 130, 132, 134 as amorphous silicon layers with relatively little to no germanium in the layers at temperatures between approximately 250 and 350 degrees Celsius may cause the band gap of the upper layer stack 106 to be at least 1.65 eV. In one embodiment, the band gap of the upper layer stack 106 formed from amorphous silicon with a germanium content in the silicon being 0.01% or less is 1.65 to 1.80 eV. The germanium content may represent the fraction or percentage of germanium in the upper layer stack 106 relative to other materials, such as silicon, in the upper layer stack 106. Decreasing the band gap of the upper layer stack 106 may cause the sublayers 130, 132, 134 to absorb a larger subset of the spectrum of wavelengths in the incident light and may result in a greater electric current to be generated by a plurality of cells 100 electrically interconnected in a series.

Deposition of the upper layer stack 106 at relatively high deposition temperatures may be verified by measuring the hydrogen content of the upper layer stack 106. In one embodiment, the final hydrogen content of the upper layer stack 106 is less than approximately 8 atomic percent if the upper layer stack 106 was deposited at temperatures above approximately 250 degrees Celsius. The final hydrogen content in the upper layer stack 106 may be measured using Secondary Ion Mass Spectrometer (SIMS). A sample of the upper layer stack 106 is placed into the SIMS. The sample is then sputtered with an ion beam. The ion beam causes secondary ions to be ejected from the sample. The secondary ions are collected and analyzed using a mass spectrometer. The mass spectrometer then determines the molecular composition of the sample. The mass spectrometer can determine the atomic percentage of hydrogen in the sample.

Alternatively, the final hydrogen concentration in upper layer stack 106 may be measured using Fourier Transform Infrared spectroscopy (“FTIR”). In FTIR, a beam of infrared light is then sent through a sample of the upper layer stack 106. Different molecular structures and species in the sample may absorb the infrared light differently. Based on the relative concentrations of the different molecular species in the sample, a spectrum of the molecular species in the sample is obtained. The atomic percentage of hydrogen in the sample can be determined from this spectrum. Alternatively, several spectra are obtained and the atomic percentage of hydrogen in the sample is determined from the group of spectra.

As described below, the top sublayer 134 may be a p-doped silicon film. In such an embodiment, the bottom and middle sublayers 130, 132 may be deposited at the relatively high deposition temperatures within the range of approximately 250 to 350 degrees Celsius while the top sublayer 134 is deposited at a relatively lower temperature within the range of approximately 150 to 200 degrees Celsius. The p-doped top sublayer 134 is deposited at the lower temperature to reduce the amount of interdiffusion between the p-doped top sublayer 134 and the intrinsic middle sublayer 132. Depositing the p-doped top sublayer 134 at a lower temperature may increase the band gap of the sublayer 134 and/or makes the sublayer 134 more transmissive of visible light.

The bottom sublayer 130 may be an amorphous layer of n-doped silicon. In one embodiment, the bottom sublayer 130 is deposited in a PECVD chamber with an operating frequency of approximately 13.56 MHz using a source gas combination of hydrogen (H₂), silane (SiH₄) and phosphine, or phosphorus trihydride (PH₃) at a vacuum pressure of approximately 2 to 3 ton and at an energy of approximately 500 to 1000 Watts. The ratio of source gases used to deposit the bottom sublayer 130 may be approximately 200 to 300 parts hydrogen gas to approximately 1 part silane to approximately 0.01 part phosphine.

The middle sublayer 132 may be an amorphous layer of intrinsic silicon. Alternatively, the middle sublayer 132 may be a polymorphous layer of intrinsic silicon. In one embodiment, the middle sublayer 132 is deposited in a PECVD chamber with an operating frequency of approximately 13.56 MHz using a source gas combination of hydrogen (H) and silane (SiH₄) at a vacuum pressure of approximately 1 to 3 ton and at an energy of approximately 200 to 400 Watts. The ratio of source gases used to deposit the middle sublayer 132 may be approximately 4 to 12 parts hydrogen gas to approximately 1 part silane.

In one embodiment, the top sublayer 134 may be a protocrystalline layer of p-doped silicon. Alternatively, the top sublayer 134 is an amorphous layer of p-doped silicon. In one embodiment, the top sublayer 134 is deposited in a PECVD chamber with an operating frequency of approximately 13.56 MHz using a source gas combination of hydrogen (H), silane (SiH₄), and boron trifluoride (BF₃), TMB, or diborane (B₂H₆) at a vacuum pressure of approximately 2 to 3 ton and at an energy of approximately 500 to 1000 Watts. The ratio of source gases used to deposit the top sublayer 126 may be approximately 200 to 300 parts hydrogen gas to approximately 1 part silane to approximately 0.01 part dopant gas.

The three sublayers 130, 132, 134 form an NIP junction of active silicon layers. The three sublayers 130, 132, 134 have an energy band gap that differs from the energy band gap of the lower layer stack 108. For example, the energy band gap of the upper layer stack 106 may be at least about 50% greater than the lower layer stack 108. In another example, the upper layer stack 106 may have an energy band gap that is at least about 60% greater than the energy band gap of the lower layer stack 108. Alternatively, the energy band gap of the upper layer stack 106 may be at least about 40% greater than the energy band gap of the lower layer stack 108. The different energy band gaps of the upper and lower layer stacks 106, 108 permit the upper and lower layer stacks 106, 108 to absorb different wavelengths of incident light and may increase the efficiency of the cell 100 in converting incident light into electric potential and/or current.

The energy band gaps of the upper and lower layer stack 106, 108 may be measured using ellipsometry. Alternatively, an external quantum efficiency (EQE) measurement may be used to obtain the energy band gaps of the upper and lower layer stacks 106, 108. The EQE measurement is obtained by varying wavelengths of light that are incident upon a semiconductor layer or layer stack and measuring the efficiency of the layer or layer stack in converting incident photons into electrons that reach the external circuit. Based on the efficiencies of the upper and lower layer stacks 106, 108 in converting incident light into electrons at different wavelengths, the energy band gaps of the upper and lower layer stacks 106, 108 may be derived. For example, each of the upper and lower layer stacks 106, 108 may be more efficient in converting incident light having an energy that is greater than the band gap of the upper or lower layer stack 106, 108 than in converting light of a different energy.

The upper electrode layer 110 is deposited above the upper layer stack 106. For example, the upper electrode layer 110 may be directly deposited onto the upper layer stack 106. The upper electrode layer 110 includes, or is formed from, a conductive and light transmissive material. For example, the upper electrode layer 110 may be formed from a transparent conductive oxide. Examples of such materials include zinc oxide (ZnO), tin oxide (SnO₂), fluorine doped tin oxide (SnO₂:F), tin-doped indium oxide (ITO), titanium dioxide (TiO₂), and/or aluminum-doped zinc oxide (Al:ZnO). The upper electrode layer 110 can be deposited in a variety of thicknesses. In some embodiments, the upper electrode layer 110 is approximately 50 nanometers to 2 micrometers thick.

In one embodiment, the upper electrode layer 110 is formed from a 60 to 90 nanometer thick layer of ITO or Al:ZnO. The upper electrode layer 110 may function as both a conductive material and a light transmissive material with a thickness that creates an anti-reflection (AR) effect in the upper electrode layer 110 of the cell 100. For example, the upper electrode layer 110 may permit a relatively large percentage of one or more wavelengths of incident light to propagate through the upper electrode layer 110 while reflecting a relatively small percentage of the wavelength(s) of light to be reflected by the upper electrode layer 110 and away from the active layers of the cell 100. By way of example only, the upper electrode layer 110 may reflect approximately 5% or less of one or more wavelengths of incident light. In another example, the upper electrode layer 110 may reflect approximately 3% or less of the light. In another embodiment, the upper electrode layer 110 may reflect approximately 2% or less of the light. In yet another example, the upper electrode layer 110 may reflect approximately 0.5% or less of the light.

The thickness of the upper electrode layer 110 may be adjusted to increase the amount of incident light that propagates through the upper electrode layer 110 and down into the upper and lower layer stacks 106, 108. Although the sheet resistance of relatively thin upper electrode layers 110 may be relatively high, such as approximately 20 to 50 ohms per square, the relatively high sheet resistance of the upper electrode layer 110 may be compensated for by decreasing a width of the upper electrode layers 110, as described below.

An adhesive layer 136 is deposited above the upper electrode layer 110. For example, the adhesive layer 136 may be deposited directly on the upper electrode layer 110. Alternatively, the adhesive layer 136 is not included in the cell 100. The adhesive layer 136 secures the cover layer 104 to the upper electrode layer 110. The adhesive layer 136 may prevent moisture ingress into the cell 100. The adhesive layer 136 may include a material such as a polyvinyl butyral (“PVB”), surlyn, or ethylene-vinyl acetate (“EVA”) copolymer, for example.

The cover layer 104 is placed above the adhesive layer 136. Alternatively, the cover layer 104 is placed on the upper electrode layer 110. The cover layer 104 includes or is formed from a light transmissive material. In one embodiment, the cover layer 104 is a sheet of tempered glass. The use of tempered glass in the cover layer 104 may help to protect the cell 100 from physical damage. For example, a tempered glass cover layer 104 may help protect the cell 100 from hailstones and other environmental damage. In another embodiment, the cover layer 104 is a sheet of soda-lime glass, low-iron tempered glass, or low-iron annealed glass. The use of a highly transparent, low-iron glass cover layer 104 can improve the transmission of light to the silicon layer stacks 106 and 108. Optionally, an AR coating (not shown) may be provided on the top of the cover layer 104.

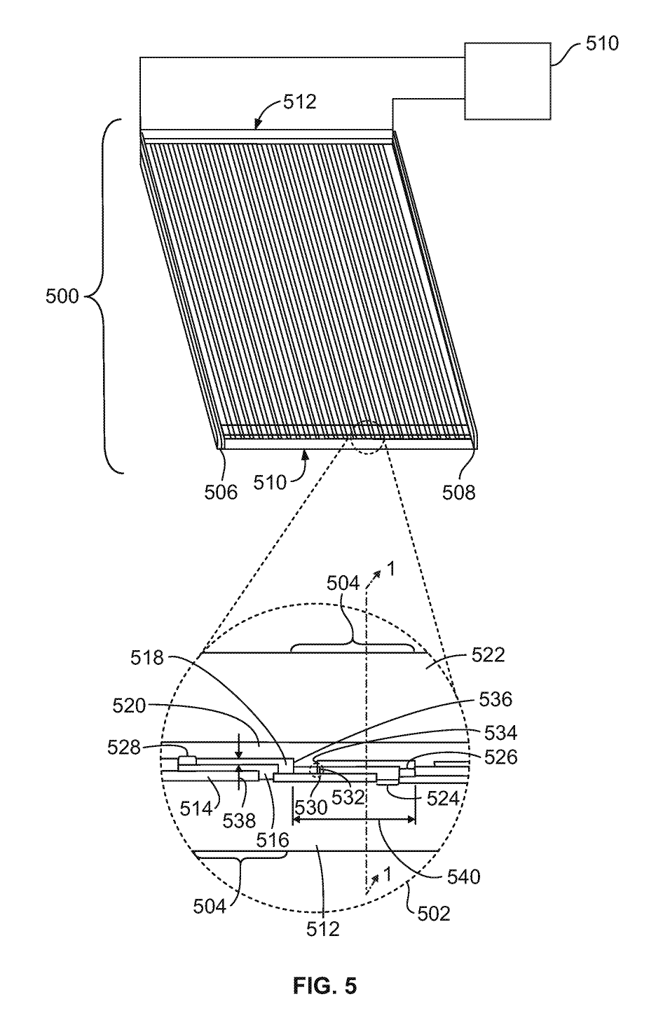

FIG. 5 is a schematic diagram of a photovoltaic device 500 and a magnified view 502 of the device 500 according to one embodiment. The device 500 includes a plurality of photovoltaic cells 504 electrically coupled in series with one another. The cells 504 may be similar to the cells 100 (shown in FIG. 1). For example, each of the cells 504 may have a tandem arrangement of upper and lower layer stacks 106, 108 that each absorb a different subset of the spectrum of wavelengths of light. The schematic illustration of FIG. 1 may be a cross-sectional view along line 1-1 in FIG. 5. The device 500 may include many cells 504 electrically coupled with one another in series. By way of example only, the device 500 may have twenty-five, fifty, or one hundred or more cells 504 connected with one another in a series. Each of the outermost cells 504 also may be electrically connected with one of a plurality of leads 506, 508. The leads 506, 508 extend between opposite ends 510, 512 of the device 500. The leads 506, 508 are connected with an external electrical load 510. The electric current generated by the device 500 is applied to the external load 510.

As described above, each of the cells 504 includes several layers. For example, each cell 504 includes a substrate 512 that is similar to the substrate 102 (shown in FIG. 1), a lower electrode layer 514 that is similar to the lower electrode layer 112 (shown in FIG. 1), a tandem silicon layer stack 516, an upper electrode layer 518 that is similar to the upper electrode layer 110 (shown in FIG. 1), an adhesive layer 520 that is similar to the adhesive layer 136 (shown in FIG. 1) and a cover layer 522 that is similar to the cover layer 104 (shown in FIG. 1). The tandem silicon layer stack 516 includes upper and lower stacks of active silicon layers that each absorb or trap a different subset of the spectrum of wavelengths of light that is incident on the device 500. For example, the tandem layer stack 516 may include the an upper layer stack that is similar to the upper active silicon layer stack 106 (shown in FIG. 1) and a lower layer stack that is similar to the lower active silicon layer stack 108 (shown in FIG. 1). The upper and lower layer stacks in the tandem layer stack 516 may be separated from one another by an intermediate reflector layer that is similar to the intermediate reflector layer 128 (shown in FIG. 1).

The upper electrode layer 518 of one cell 504 is electrically coupled with the lower electrode layer 514 in a neighboring, or adjacent, cell 100. As described above, the collection of the electrons and holes at the upper and lower electrode layers 518, 514 generates a voltage difference in each of the cells 504. The voltage difference in the cells 504 may be additive across multiple cells 504 in the device 500. The electrons and holes flow through the upper and lower electrode layers 518, 514 in one cell 504 to the opposite electrode layer 518, 514 in a neighboring cell 504. For example, if the electrons in a first cell 504 flow to the lower electrode layer 514 in a when light strikes the tandem layer stack 516, then the electrons flow through the lower electrode layer 514 of the first cell 504 to the upper electrode layer 518 in a second cell 504 that is adjacent to the first cell 504. Similarly, if the holes flow to the upper electrode layer 518 in the first cell 504, then the holes flow from the upper electrode layer 518 in the first cell 504 to the lower electrode layer 514 in the second cell 504. Electric current and voltage is generated by the flow of electrons and holes through the upper and lower electrode layers 518, 514. The current is applied to the external load 510.

The device 500 may be a monolithically integrated solar module similar to one or more of the embodiments described in co-pending U.S. Nonprovisional patent application Ser. No. 12/569,510, filed Sep. 29, 2009, and entitled “Monolithically-Integrated Solar Module” (“'510 Application”). The entire disclosure of the '510 Application is incorporated by reference herein. For example, in order to create the shapes of the lower and upper electrode layers 514, 518 and the tandem layer stack 516 in the device 500, the device 500 may be fabricated as a monolithically integrated module as described in the '510 Application. In one embodiment, portions of the lower electrode layer 514 are removed to create lower separation gaps 524. The portions of the lower electrode layer 514 may be removed using a patterning technique on the lower electrode layer 514. For example, a laser light that scribes the lower separation gaps 524 in the lower electrode layer 514 may be used to create the lower separation gaps 524. After removing portions of the lower electrode layer 514 to create the lower separation gaps 524, the remaining portions of the lower electrode layer 514 are arranged as linear strips extending in directions transverse to the plane of the magnified view 502.

The tandem layer stack 516 is deposited on the lower electrode layer 514 such that the tandem layer stack 516 fills in the volumes in the lower separation gaps 524. The tandem layer stack 516 is then exposed to a focused beam of energy, such as a laser beam, to remove portions of the tandem layer stack 516 and provide inter-layer gaps 526 in the tandem layer stack 516. The inter-layer gaps 526 separate the tandem layer stacks 516 of adjacent cells 504. After removing portions of the tandem layer stacks 516 to create the inter-layer gaps 526, the remaining portions of the tandem layer stacks 516 are arranged as linear strips extending in directions transverse to the plane of the magnified view 502.

The upper electrode layer 518 is deposited on the tandem layer stack 516 and on the lower electrode layer 514 in the inter-layer gaps 526. In one embodiment, the conversion efficiency of the device 500 may be increased by depositing a relatively thin upper electrode layer 518 with a thickness that is adjusted or tuned to provide an anti-reflection effect. For example, a thickness 538 of the upper electrode layer 518 may be adjusted to increase the amount of visible light that is transmitted through the upper electrode layer 518 and into the tandem layer stack 516. The amount of visible light that is transmitted through the upper electrode layer 518 may vary based on the wavelength of the incident light and the thickness of the upper electrode layer 518. One thickness of the upper electrode layer 518 may permit more light of one wavelength to propagate through the upper electrode layer 518 than light of other wavelengths. By way of example only, the upper electrode layer 518 may be deposited at a thickness of approximately 60 to 90 nanometers.

In terms of increasing the total power generated by the PV device 500, the increased power output arising from the anti-reflection effect provided by a thin upper electrode layer 518 may be sufficient to overcome at least some, if not all, of energy losses that may occur in the upper electrode layer 518. For example, some I²R losses of the photocurrent that is generated by the cell 504 may occur in the relatively thin upper electrode layer 518 due to the resistance of the upper electrode layer 518. But, an increased amount of photocurrent may be generated due to the thickness of the upper electrode layer 518 being based on a wavelength of the incident light to increase the amount of incident light that passes through the upper electrode layer 518. The increased amount of photocurrent may result from an increased amount of light passing through the upper electrode layer 518. The increased photocurrent may overcome or at least partially compensate for the I²R power loss associated with the relatively high sheet resistance of a thin upper electrode layer 518.

By way of example only, in a cell 504 having one amorphous silicon junction layer stack and one microcrystalline silicon junction stacked in series in the tandem layer stack 516, an output voltage in the range of approximately 1.25 to 1.5 volts and an electric current density in the range of approximately 10 to 15 milliamps per square centimeter may be achieved. I²R losses in a thin upper electrode layer 518 of the cell 504 may be sufficiently small that a width 540 of the cell 504 may be increased even if the upper electrode layer 518 has a relatively high sheet resistance. For example, the width 540 of the cell 504 may be increased to as large as approximately 0.4 to 1 centimeter even if the sheet resistance of the upper electrode layer 518 is at least 10 ohms per square, such as a sheet resistance of at least approximately 15 to 30 ohms/square. Because the width 540 of the cell 504 can be controlled in the device 500, the I²R power loss in the upper electrode layer 518 may be reduced without the use or addition of a conducting grid on top of a thin upper electrode layer 518.

Portions of the upper electrode layer 518 are removed to create upper separation gaps 528. The upper separation gaps 528 electrically separate portions of the upper electrode layer 518 that are in adjacent cells 504. The upper separation gaps 528 may be created by exposing the upper electrode layer 518 to a focused beam of energy, such as a laser light. The focused beam of energy may locally increase the crystallinity of the tandem layer stack 516 proximate to the upper separation gaps 528. For example, a crystalline fraction of the tandem layer stack 516 in a vertical portion 530 that extends between the upper electrode layer 518 and the lower electrode layer 514 may be increased by exposure to the focused beam of energy. Additionally, the focused beam of energy may cause diffusion of dopants within the tandem layer stack 516. The vertical portion 530 of the tandem layer stack 516 is disposed between the upper and lower electrode layers 518, 514 and below a left edge 534 of the upper electrode layer 518. As shown in FIG. 5, each of the gaps 528 in the upper electrode layer 518 are bounded by the left edge 534 and an opposing right edge 536 of the upper electrode layers 518 in adjacent cells 504.

The crystalline fraction of the tandem layer stack 516 and the vertical portion 530 may be determined by a variety of methods. For example, Raman spectroscopy can be used to obtain a comparison of the relative volume of noncrystalline material to crystalline material in the tandem layer stack 516 and the vertical portion 530. One or more of the tandem layer stack 516 and the vertical portion 530 sought to be examined can be exposed to monochromatic light from a laser, for example. Based on the chemical content and crystal structure of the tandem layer stack 516 and the vertical portion 530, the monochromatic light may be scattered. As the light is scattered, the frequency (and wavelength) of the light changes. For example, the frequency of the scattered light can shift. The frequency of the scattered light is measured and analyzed. Based on the intensity and/or shift in the frequency of the scattered light, the relative volumes of amorphous and crystalline material of the tandem layer stack 516 and the vertical portion 530 being examined can be determined. Based on these relative volumes, the crystalline fraction in the tandem layer stack 516 and the vertical portion 530 being examined may be measured. If several samples of the tandem layer stack 516 and the vertical portion 530 are examined, the crystalline fraction may be an average of the several measured crystalline fractions.

In another example, one or more TEM images can be obtained of the tandem layer stack 516 and the vertical portion 530 to determine the crystalline fraction of the tandem layer stack 516 and the vertical portion 530. One or more slices of the tandem layer stack 516 and the vertical portion 530 being examined are obtained. The percentage of surface area in each TEM image that represents crystalline material is measured for each TEM image. The percentages of crystalline material in the TEM images can then be averaged to determine the crystalline fraction in the tandem layer stack 516 and the vertical portion 530 being examined.

In one embodiment, the increased crystallinity and/or the diffusion of the vertical portion 530 relative to a remainder of the tandem layer stack 516 forms a built-in bypass diode 532 that vertically extends through the thickness of the tandem layer stack 516 in the view shown in FIG. 5. For example, the crystalline fraction and/or interdiffusion of the tandem stack 516 in the vertical portion 530 may be greater than the crystalline fraction and/or interdiffusion in a remainder of the tandem stack 516. Through control of the energy and pulse duration of the focused beam of energy, the built-in bypass diode 532 can be formed through individual ones of the individual cells 504 without creating an electrical short in the individual cells 504. The built-in bypass diode 532 provides an electrical bypass through a cell 504 in the device 500.

Without the built-in bypass diodes 532, a cell 504 that is shaded or no longer exposed to light while the other cells 504 continue to be exposed to light may become reversed biased by the electric potential generated by the exposed cells 504. For example, the electric potential generated by the light-exposed cells 504 may be built up across the shaded cell 504 at the upper and lower electrode layers 518, 514 of the shaded cell 504. As a result, the shaded cell 504 may increase in temperature and, if the shaded cell 504 significantly increases in temperature, the shaded cell 504 may become permanently damaged and/or incinerate. In addition, a shaded cell 504 that does not have a built-in bypass diode 532 may prevent electric potential or current from being generated by the entire device 500.

With the built-in bypass diodes 532, the electric potential generated by the exposed cells 504 may bypass the shaded cell 504 through the bypass diodes 532 formed at the edges of the upper separation gaps 528 of the shaded cell 504. The increased crystallinity of the portion 530 of the tandem layer stack 516 and/or interdiffusion between the upper electrode layer 518 and the portion 530 in the tandem layer stack 516 provides a path for electric current to pass through when the shaded cell 504 is reverse biased. For example, the reverse bias across the shaded cell 504 may be dissipated through the bypass diodes 532 as the bypass diodes 532 have a lower electrical resistance characteristic under reverse bias than the bulk of the shaded cell 504.

The presence of built-in bypass diodes 532 may be determined by comparing the electrical output of the device 500 before and after shading an individual cell 504. For example, the device 500 may be illuminated and the electrical potential generated by the device 500 is measured. One or more cells 504 may be shaded from the light while the remaining cells 504 are illuminated. The device 500 may be short circuited by joining the leads 506, 508 together. The device 500 may then be exposed to light for a predetermined time period, such as one hour. Both the shaded cells 504 and the unshaded cells 504 are then once again illuminated and the electrical potential generated by the device 500 is measured. If the electrical potential before and after the shading of the cells 504 is within approximately 100 millivolts of one another, then the device 500 may include built-in bypass diodes 532. Alternatively, if the electrical potential after the shading of the cells 504 is approximately 200 to 1500 millivolts lower than the electrical potential prior to the shading of the cells 504, then the device 500 likely does not include the built-in bypass diodes 532. In another embodiment, the presence of a built-in bypass diode 532 for a particular cell 504 may be determined by electrically probing the cell 504. If the cell 504 demonstrates a reversible, non-permanent diode breakdown when the cell 504 is reverse biased without illumination, then the cell 504 includes the built-in bypass diode 532. For example, if the cell 504 demonstrates greater than approximately 10 milliamps per square centimeter of leakage current when a reverse bias of approximately −5 to −8 volts is applied across the upper and lower electrode layers 514, 518 of the cell 504 without illumination, then the cell 504 includes the built-in bypass diode 532.

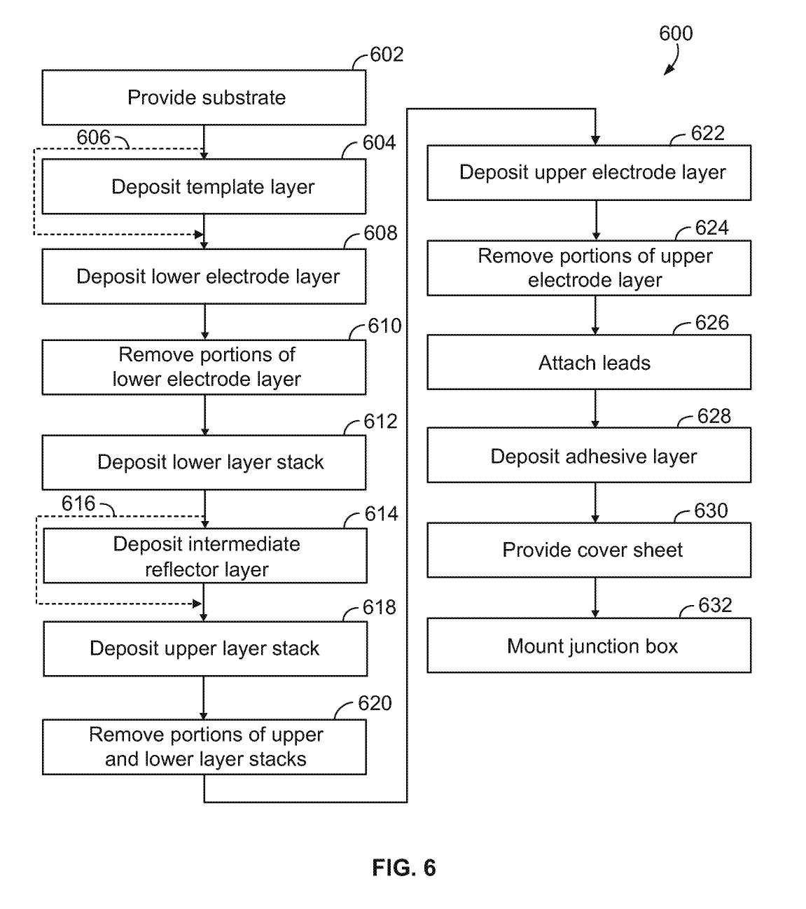

FIG. 6 is a flowchart of a process 600 for manufacturing a photovoltaic device in accordance with one embodiment. At 602, a substrate is provided. For example, a substrate such as the substrate 102 (shown in FIG. 1) may be provided. At 604, a template layer is deposited onto the substrate. For example, the template layer 114 (shown in FIG. 1) may be deposited onto the substrate 102. Alternatively, flow of the process 600 may bypass 604 along a path 606 such that no template layer is included in the photovoltaic device. At 608, a lower electrode layer is deposited onto the template layer or the substrate. For example, the lower electrode layer 112 (shown in FIG. 1) may be deposited onto the template layer 114 or the substrate 102.

At 610, portions of the lower electrode layer are removed to separate the lower electrode layer of each cell in the device from one another. As described above, portions of the lower electrode layer may be removed using a focused beam of energy, such as a laser beam. At 612, a lower active silicon layer stack is deposited. For example, the lower layer stack 108 (shown in FIG. 1) may be deposited onto the lower electrode layer 112 (shown in FIG. 1). At 614, an intermediate reflector layer is deposited above the lower layer stack. For example, the intermediate reflector layer 128 (shown in FIG. 1) may be deposited onto the lower layer stack 106. Alternatively, flow of the process 600 bypasses deposition of the intermediate reflector layer at 614 along path 616. At 618, an upper active silicon layer stack is deposited above the intermediate reflector layer or the lower layer stack. For example, in one embodiment, the upper layer stack 106 (shown in FIG. 1) is deposited onto the intermediate reflector layer 128. Alternatively, the upper layer stack 106 may be deposited onto the lower layer stack 108.

At 620, portions of the upper and lower layer stacks are removed between adjacent cells in the device. For example, sections of the upper and lower layer stacks 106, 108 (shown in FIG. 1) may be removed between adjacent cells 504 (shown in FIG. 5), as described above. At 622, an upper electrode layer is deposited above the upper and lower layer stacks. For example, the upper electrode layer 110 (shown in FIG. 1) may be deposited above the upper and lower layer stacks 106, 108. At 624, portions of the upper electrode layer are removed. For example, portions of the upper electrode layer 110 are removed to separate the upper electrode layers 110 of adjacent cells 504 in the device 500 (shown in FIG. 5) from one another. As described above, removal of portions of the upper electrode layer 110 may result in built-in bypass diodes in being formed in the upper layer stack 106.

At 626, conductive leads are electrically joined to the outermost cells in the device. For example, the leads 506, 508 (shown in FIG. 5) may be electrically coupled with the outermost cells 504 (shown in FIG. 5) in the device 500 (shown in FIG. 5). At 628, an adhesive layer is deposited above the upper electrode layer. For example, the adhesive layer 136 (shown in FIG. 1) may be deposited above the upper electrode layer 110 (shown in FIG. 1). At 630, a cover layer is affixed to the adhesive layer. For example, the cover layer 104 (shown in FIG. 1) may be joined to the underlying layers and components of the cell 100 (shown in FIG. 1) by the adhesive layer 136. At 632, a junction box is mounted to the device. For example, a junction box that is configured to deliver electric potential and/or current from the device 500 to one or more connectors may be mounted to and electrically coupled with the device 500.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter described herein without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the subject matter disclosed herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A monolithically-integrated photovoltaic module comprising:
an insulating substrate;
a lower electrode disposed above the substrate;
a lower stack of microcrystalline silicon layers disposed above the lower electrode;
an upper stack of amorphous silicon layers disposed above the lower stack of microcrystalline silicon layers, the lower and upper stacks having different energy band gaps;
an upper electrode disposed above the upper stack of amorphous silicon layers; and
a built-in bypass diode vertically extending in the lower stack of microcrystalline silicon layers and the upper stack of amorphous silicon layers from the lower electrode to the upper electrode, the built-in bypass diode comprising portions of the lower stack of microcrystalline silicon layers and the upper stack of amorphous silicon layers that have a greater crystalline fraction than a remainder of the lower stack of microcrystalline silicon layers and the upper stack of amorphous silicon layers.

2. The photovoltaic module of claim 1, wherein the bypass diode is formed in a photovoltaic cell of the device and conducts electric current through the lower stack of microcrystalline silicon layers and the upper stack of amorphous silicon layers when the photovoltaic cell is reverse biased between adjacent photovoltaic cells in the device.

3. The photovoltaic module of claim 1, wherein the bypass diode conducts electric current between the upper and lower electrodes and through the upper stack of amorphous silicon layers and the lower stack of microcrystalline silicon layers of a photovoltaic cell of the device when the upper stack of amorphous silicon layers and the lower stack of microcrystalline silicon layers in the cell are shaded from light but one or more adjacent cells are exposed to light.

4. The photovoltaic module of claim 1, wherein the energy band gap of the upper stack of amorphous silicon layers is at least 50% greater than the energy band gap of the lower stack of microcrystalline silicon layers.

5. The photovoltaic module of claim 1, wherein the energy band gap of the upper stack of amorphous silicon layers is at least 1.65 eV.

6. The photovoltaic module of claim 5, wherein a germanium content of the upper stack of amorphous silicon layers is less than 0.01%.

7. The photovoltaic module of claim 1, wherein the energy band gap of the upper stack of amorphous silicon layers is 1.85 eV or less.

8. The photovoltaic module of claim 1, wherein the amorphous silicon layers of the upper stack include a hydrogen content of less than about 10 atomic percent.

9. The photovoltaic module of claim 1, further comprising an intermediate reflector layer between the upper stack of amorphous silicon layers and the lower stack of microcrystalline silicon layers, wherein the reflector layer reflects a portion of incident light into the upper stack of amorphous silicon layers and permits another portion of the light to pass into the lower stack of microcrystalline silicon layers.

10. A method of manufacturing a photovoltaic module, the method comprising:
providing a substrate;
depositing a lower electrode above the substrate;
depositing a lower stack of microcrystalline silicon layers above the lower electrode;
depositing an upper stack of amorphous silicon layers above the lower stack of microcrystalline silicon layers; and
depositing an upper electrode above the upper stack of amorphous silicon layers, wherein at least one of the lower stack and upper stack includes an N-I-P stack of silicon layers having an n-doped silicon layer, an intrinsic silicon layer, and a p-doped silicon layer with the intrinsic silicon layer having an energy band gap that is reduced by depositing the intrinsic silicon layer at a temperature of at least 250 degrees Celsius.

11. The method of claim 10, wherein the lower stack includes the N-I-P stack and the depositing the lower stack comprises depositing the intrinsic silicon layer at the temperature of at least 250 degrees Celsius.

12. The method of claim 10, wherein the upper stack includes the N-I-P stack and the depositing the upper stack comprises depositing the intrinsic silicon layer at the temperature of at least 250 degrees Celsius.

13. The method of claim 10, wherein the depositing the lower stack and the depositing the upper stack comprise depositing the lower and upper stacks such that an energy band gap of the upper stack is at least 50% greater than an energy band gap of the lower stack.

14. The method of claim 10, wherein the depositing the upper stack comprises depositing the upper stack such that the upper stack has an energy band gap of at least 1.65 eV.

15. The method of claim 10, wherein the depositing the upper stack comprises depositing the upper stack such that the upper stack has an energy band gap of 1.85 eV or less.

16. The method of claim 10, further comprising increasing a crystallinity of the lower stack and of the upper stack by removing a portion of the upper electrode, the crystallinity of the lower stack and of the upper stack increased to form a built-in bypass diode that extends from the lower electrode to the upper electrode and through the upper stack and the lower stack.

17. The method of claim 16, further comprising electrically conducting photocurrent between the upper and lower electrodes through the built-in bypass diode when a photovoltaic cell that includes the built-in bypass diode is shaded from incident light and adjacent photovoltaic cells are exposed to the light or when a photovoltaic cell that includes the built-in bypass diode is reverse biased.

18. A method of manufacturing a photovoltaic module, the method comprising:
providing a substrate and a lower electrode;
depositing a lower stack of microcrystalline silicon layers above the lower electrode;
depositing an upper stack of amorphous silicon layers above the lower stack;
providing an upper electrode above the upper stack of amorphous silicon layers; and
increasing a crystallinity of the lower stack and of the upper stack by removing a portion of the upper electrode, the crystallinity of the lower stack and of the upper stack increased to form a built-in bypass diode that extends from the lower electrode to the upper electrode and through the lower stack and the upper stack.

19. The method of claim 18, wherein the increasing comprises exposing the upper electrode to a focused beam of energy that removes the upper electrode to electrically separate portions of the upper electrode in adjacent cells of the photovoltaic device.

20. The method of claim 18, further comprising electrically conducting photocurrent between the upper and lower electrodes through the built-in bypass diode when a photovoltaic cell that includes the built-in bypass diode is shaded from incident light and adjacent photovoltaic cells are exposed to the light or when a photovoltaic cell that includes the built-in bypass diode is reverse biased.
